(19) United States
(12) Patent Application Publication
(10) Pub. No.: US 2007/0102780 A1
(43) Pub. Date: May 10, 2007

(54) LOW DARK CURRENT CMOS IMAGE SENSOR PIXEL HAVING A PHOTODIODE ISOLATED FROM FIELD OXIDE

(76) Inventor: Qiang Luo, Santa Clara, CA (US)

Correspondence Address: Frank Pincelli, Patent Legal Staff;Eastman Kodak Company, 343 State Street, Rochester, NY, 14650-2201, US

(21) Appl. No.: 11/619,646

(22) Filed: Jan. 4, 2007

Related U.S. Application Data
(62) Division of application No. 10/786,846, filed on Feb. 25, 2004, now abandoned.

(51) Int. Cl. H01L 31/06; H01L 27/14

(52) U.S. Cl. 257/461; 257/431

(57) ABSTRACT

A low dark current CMOS image sensor pixel comprises a photodiode that is isolated from the field oxide by forming a relatively small photodiode within a relatively large active area such that the field oxide is substantially separated from the photodiode. The active area should be large enough such that the photodiode depletion region formed during operation of the photodiode does not touch the field oxide sidewall and corner. The isolation of the photodiode from the field oxide significantly reduces the number of dislocations near the field oxide that contribute to the dark current. Accordingly, the isolation of the photodiode from the field oxide dramatically reduces the dark current of the photodiode during operation. The present invention can be formed with a conventional CMOS process without adding any additional process steps.

### CROSS-REFERENCE TO RELATED APPLICATIONS

This is a divisional of U.S. application Ser. No. 10/786,846, filed Feb. 25, 2004.

### FIELD OF THE INVENTION

The present invention relates generally to CMOS image sensors, and more particularly to CMOS image sensor pixel architecture.

### BACKGROUND OF THE INVENTION

Electronic image sensors are widely used to produce video and photographic images. The electronic image sensors typically comprise pixel sensors (pixels) that are arranged in an array of rows and columns. Each pixel comprises a photodetector, which is typically a photodiode. Incident light upon a pixel sensor discharges the photodiode such that the resulting voltage drop can be used to determine the intensity level the incident light.

“Dark current” of an electronic image sensor is the leakage current that is discharged from the photodiode even when there is no incident light upon the sensor. Dark current is present in both common types of image sensors: CCD and CMOS image sensors. Typical dark current levels in CMOS image sensors (using conventional technology) is usually more than an order of magnitude larger than the dark current levels of a CCD image sensor (manufactured with an optical fabrication process and using advanced dark current management techniques) having a comparable resolution.

Dark currents predominantly arise from stress-related dislocations that are formed in the area around the interface between the field oxide and the photodiode of a pixel and the Si—SiO₂ interface. Dark current is caused when, for example, electrons that are formed in the bird's beak area of LOCOS or STI sidewall and corner are separated from their counterpart holes by the electrical field generated in the depletion region of a photodiode, such that the electrons are collected by the n+ photodiode cathode.

An appreciation of the present invention and its improvements can be obtained by reference to the accompanying drawings, which are briefly summarized below, to the following detailed description of illustrated embodiments of the invention, and to the appended claims.

### BRIEF DESCRIPTION OF THE DRAWINGS

FIG. 1 is a schematic diagram of a three-transistor active pixel sensor in accordance with the present invention.

FIGS. 2a and 2b are schematic diagrams of cross sections of conventional n+ photodiode structures with each having a corresponding depletion region.

FIGS. 3a-3c are schematic diagrams of a process used to form a photodiode, in accordance with the present invention.

FIGS. 4a and 4b are schematic diagrams of cross sections of n+ photodiode structures with each having a corresponding depletion region, in accordance with the present invention.

FIG. 5 is a schematic diagram of a top view of a low dark current pixel layout architecture, in accordance with the present invention.

### DETAILED DESCRIPTION OF THE INVENTION

In the following detailed description of exemplary embodiments of the invention, reference is made to the accompanied drawings, which form a part hereof, and which is shown by way of illustration, specific exemplary embodiments of which the invention may be practiced. These embodiments are described in sufficient detail to enable those skilled in the art to practice the invention, and it is to be understood that other embodiments may be utilized, and other changes may be made, without departing from the spirit or scope of the present invention. The following detailed description is, therefore, not to be taken in a limiting sense, and the scope of the present invention is defined only by the appended claims.

Throughout the specification and claims, the following terms take the meanings explicitly associated herein, unless the context clearly dictates otherwise. The meaning of “a,” “an,” and “the” includes plural reference, the meaning of “in” includes “in” and “on.” The term “connected” means a direct electrical connection between the items connected, without any intermediate devices. The term “coupled” means either a direct electrical connection between the items connected, or an indirect connection through one or more passive or active intermediary devices. The term “circuit” means either a single component or a multiplicity of components, either active and/or passive, that are coupled together to provide a desired function. The term “signal” means at least one current, voltage, or data signal. Referring to the drawings, like numbers indicate like parts throughout the views.

The present invention is directed towards a low dark current CMOS image sensor pixel. In an example embodiment, the photodiode of the pixel is isolated from the field oxide by forming a relatively small photodiode within a relatively large active area such that the field oxide is substantially separated from the photodiode. The active area should be large enough such that the photodiode depletion region formed during operation of the photodiode does not touch the field oxide sidewall and corner. The isolation of the photodiode from the field oxide significantly reduces the number of dislocations near the field oxide that contribute to the dark current. Accordingly, the isolation of the photodiode from the field oxide dramatically reduces the dark current of the photodiode during operation. The present invention can be formed with a conventional CMOS process without adding any additional process steps.

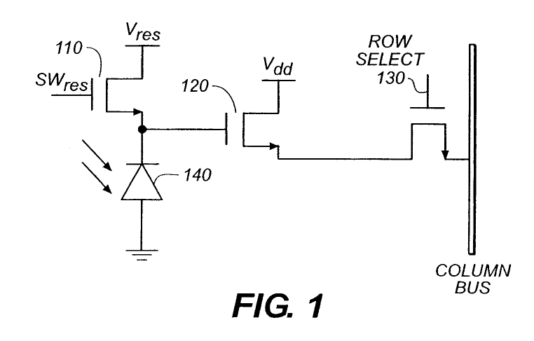

FIG. 1 is a schematic diagram of a three-transistor active pixel sensor in accordance with the present invention. In operation, SWᵣₑₛ provides the reset pulse to reset transistor 110 to set the initial potential of the photodiode 140. The photodiode cathode is coupled to the gate of a source-follower transistor 120 to produce a buffered output signal at the source of transistor 120. The buffered output signal is coupled to a column bus (of a pixel array) through select transistor 130 that is controlled by a row select pulse.

The photodiode is typically reset first to an initial level (e.g., Vᵣₑₛ) by pulsing SWᵣₑₛ high. At the falling edge of the SWᵣₑₛ pulse, reset transistor 110 is turned off. The incident light-generated current then starts to discharge the photodiode. After certain time interval, the photodiode voltage of photodiode 140 is read out by pulsing the row select signal high. Next, photodiode 140 is reset again and the initial photodiode voltage is also read out. The difference between these two readout voltages can be used to determine the voltage drop caused by the incident light during that certain time interval.

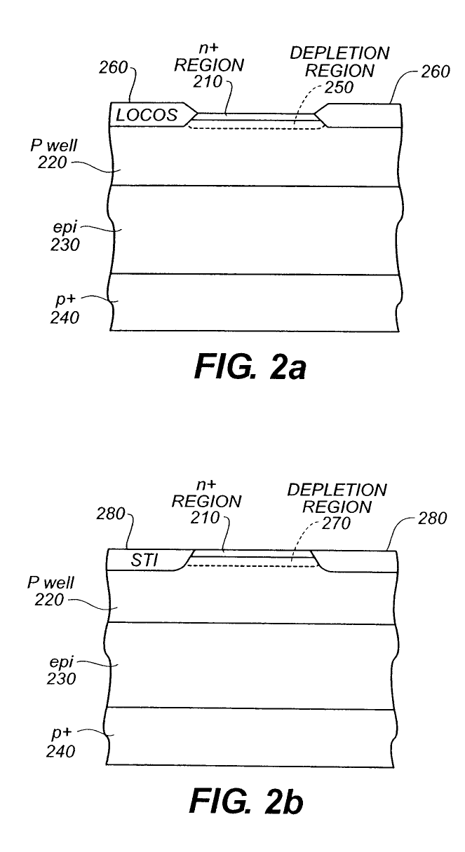

FIGS. 2a and 2b are schematic diagrams of cross sections of conventional n+ photodiode structures with each having a corresponding depletion region. The structures can be manufactured using a twin-well (P well and N well) process. The conventional n+ photodiode comprises an n+ region 210 that is situated on P well 220. Lightly doped P type epitaxial layer 230 underlies P well 220 and overlies p+ substrate 240. In accordance with conventional n+photodiode structures, the depletion region touches the field oxide. The field oxide can be implemented using a LOCOS (Local Oxidation of Silicon) or an STI (Shallow Trench Isolation) process.

In FIG. 2a, a conventional n+ photodiode formed using a LOCOS process step is shown. In operation, depletion region 250 is formed such that depletion region 240 is contiguous with the “bird's beak” of LOCOS structure 260. In FIG. 2b, a conventional n+ photodiode formed using an STI process step is shown. In operation, the depletion region 270 is contiguous with the sidewall of STI structure 280 and possibly with the sidewall corner of STI structure 280 as well. Stress-related dislocations in conventional n+ photodiodes are included in the depletion region 250 (or 270) and produce dark current.

In accordance with the present invention, a photodiode depletion region is isolated from the field oxide, which reduces the dark current of a photodiode in accordance with the present invention. The dark current is reduced because the dislocations are the cause of a substantial amount of the dark current of the photodiode. The depletion region is isolated from the field oxide in accordance with the present invention by increasing the size of the opening in the field oxide and forming an n+ photodiode that is substantially contained within the boundaries defined by the opening.

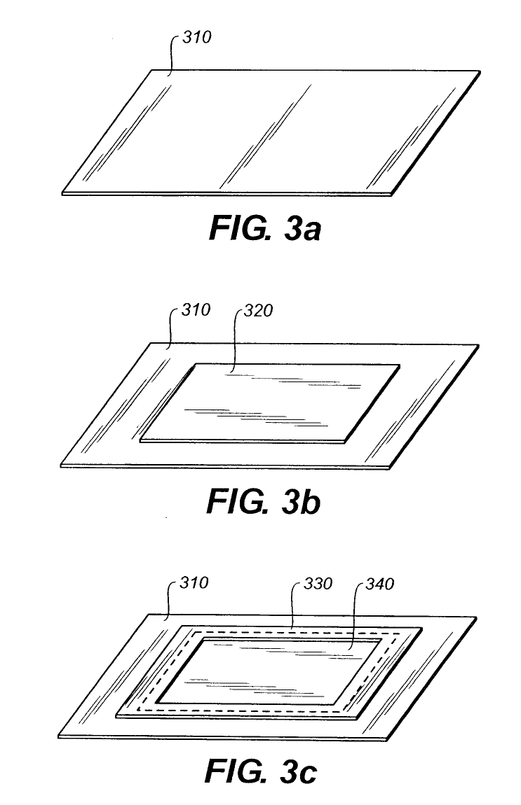

FIGS. 3a-3c are schematic diagrams of a process used to form a photodiode, in accordance with the present invention. In FIG. 3a, a field oxide region (310) is initially formed, typically on a P well structure. In FIG. 3b, an active area (320) is formed within field oxide region 310 such that active area 320 can substantially encompass a later-deposited n+ region.

After the active area is formed, blocking layer 330 (which is typically used for defining the outer boundaries of a later-deposited n+ region) is formed such that the blocking layer overlaps active area 320 and field oxide region 310 and that the interface between the active area and the field oxide region is covered (see FIG. 3c). Blocking layer 330 comprises an opening through which the n+ region is formed. Accordingly, the area around the boundaries of the photodiode active area (320) is blocked during a process step that is used to form the n+ region of the photodiode in accordance with the present invention.

The n+ region (340) can be formed by implanting, for example, arsenic in the active area that is not blocked by blocking layer 330. Accordingly, the n+ region is offset from the edge of the field oxide by an offset that is related to the degree of overlap of the blocking layer. The offset of the n+ region to the field oxide should be sufficiently wide such that the depletion region (which is formed around the n+ region) in operation does not touch the field oxide.

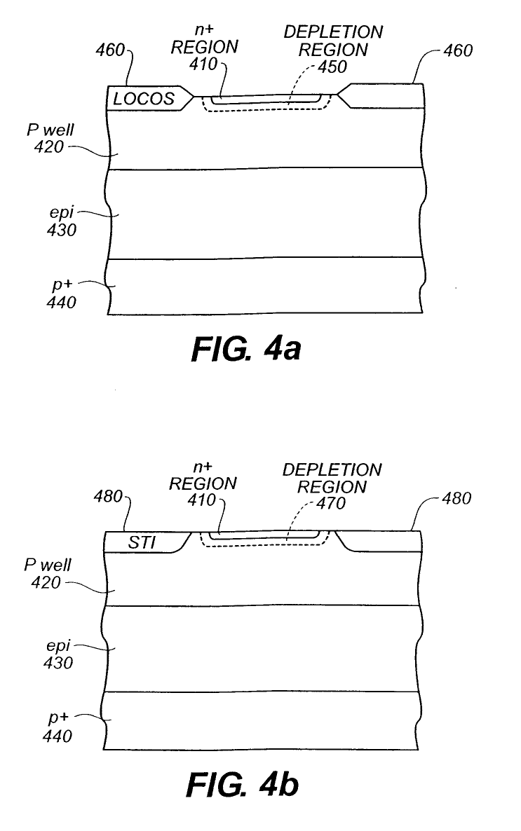

FIGS. 4a and 4b are schematic diagrams of cross sections of n+ photodiode structures with each having a corresponding depletion region, in accordance with the present invention. The structures can be manufactured using a twin-well (P well and N well) process. The n+ photodiode comprises an n+ region 410 that is situated on P well 420. Lightly doped P type epitaxial layer 430 underlies P well 420 and overlies p+ substrate 440. In accordance with the n+ photodiode structures in accordance with the present invention, the depletion region is isolated from the field oxide. The field oxide can be implemented using a LOCOS or an STI process.

In FIG. 4a, an n+ photodiode formed using a LOCOS process step in accordance with the present invention is shown. In operation, depletion region 450 is formed such that depletion region 440 is isolated from the bird's beak of LOCOS structure 460. In FIG. 4b, an n+ photodiode formed using an STI process step in accordance with the present invention is shown. In operation, the depletion region 470 is isolated from the sidewall of STI structure 480 as well as the sidewall corner of STI structure 480.

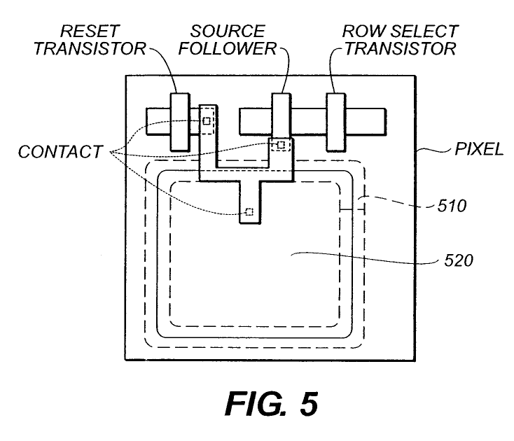

Since the depletion region of the pixel photodiode is isolated from field oxide, the defects (i.e., stress-related dislocations) at the field oxide bird's beak (or sidewall and corner) are not included in the depletion region. In operation, electrons that are formed in the bird's beak area of LOCOS or STI sidewall and corner are most likely to recombine with holes in the surrounding p-well region rather than being collected by the n+ photodiode as is the case when the photodiode adjoins a field oxide region FIG. 5 is a schematic diagram of a top view of a low dark current pixel layout architecture, in accordance with the present invention. As shown in the figure, photodiode 520 is shown as being formed within the area bounded by blocking layer 510.

For further dark current reduction, a buried photodiode can be used to isolate the photodiode from the surface of silicon to further reduce dark current. A buried diode can be formed by depositing a transparent insulation layer over the photodiode region.

The structure can be formed without process modifications (such as extra masks or process steps) and can be successfully implemented using standard CMOS logic processes. For a typical 0.18 μm CMOS process, the distance between active area boundaries and photodiode is typically about 0.3 μm. Accordingly, the reduction of the fill factor is virtually negligible because the distance between active area boundaries and photodiode is comparatively much smaller than the photodiode size.

Various embodiments of the invention are possible without departing from the spirit and scope of the invention. The above specification, examples and data provide a complete description of the manufacture and use of the composition of the invention. For example, the P well on epitaxial layer 430 may be formed by electrically coupling separate P well structures. Since many embodiments of the invention can be made without departing from the spirit and scope of the invention, the invention resides in the claims hereinafter appended.

1. An imaging pixel, comprising:
a first well of a first polarity type;
a first oxide layer that is formed on the surface of the first well such that the first oxide layer comprises an opening through which a portion of the first well is exposed; and
a diode electrode structure of a second polarity type that is opposite the first polarity type wherein the diode electrode structure is formed within an area that is within the exposed portion of the first well such that an intervening portion of the exposed portion of the first well exists between the diode electrode structure and the first oxide layer.

2. The pixel of claim 1, wherein the diode electrode structure is formed using an arsenic implant process.

3. The pixel of claim 1, wherein the intervening portion of the first well forms a continuous area surrounding the diode electrode structure.

4. The pixel of claim 1, wherein the diode electrode structure is formed such that a substantial portion of a depletion region that results when a bias voltage is applied to the diode electrode structure does not extend to the first oxide layer.

5. The pixel of claim 1, further comprising a reset transistor that is configured to set an initial voltage across the first well and the diode electrode structure.

6. The pixel of claim 1, wherein the oxide layer is formed using a local oxidation of silicon process.

7. The pixel of claim 1, wherein the oxide layer is formed using a shallow trench isolation process.

8. An imaging pixel, comprising:
a first well means of a first polarity type;
an insulation means that is formed on the surface of the first well means such that the insulation means comprises an opening through which a portion of the first well means is exposed; and
a diode electrode means of a second polarity type that is opposite the first polarity type wherein the diode electrode means is formed within an area that is within the exposed portion of the first well means such that an intervening portion of the exposed portion of the first well means exists between the diode electrode means and the insulation means.

9. The pixel of claim 8, wherein the intervening portion of the first well means forms a continuous area surrounding the diode electrode means.

10. The pixel of claim 9, further comprising terminals that are configured to apply a bias voltage across the first well means and the diode electrode means.

11. The pixel of claim 8, wherein the diode electrode means is formed such that a substantial portion of a depletion region that results when a bias voltage is applied to the diode electrode means does not extend to the insulation means.
